(19) United States
(12) Patent Application Publication
(10) Pub. No.: US 2026/0290450 A1
(43) Pub. Date: Sep. 24, 2026

(54) EFFICIENT AND HIGH PERFORMANCE WRITE ARCHITECTURE FOR HIGH DENSITY RESISTIVE RANDOM ACCESS MEMORY

(71) Applicant: IM2 Solutions, Inc., Pleasanton, CA (US)

(72) Inventors: Adrian ONG, Pleasanton, CA (US); Tim LAO, Sacramento, CA (US)

(73) Assignee: IM2 Solutions, Inc., Pleasanton, CA (US)

(21) Appl. No.: 19/572,853

(22) Filed: Mar. 19, 2026

Related U.S. Application Data
(60) Provisional application No. 63/774,733, filed on Mar. 19, 2025.

(51) Int. Cl. G11C 13/00

(52) U.S. Cl. CPC G11C 13/0026; G11C 13/0038; G11C 13/0069

(57) ABSTRACT

A high-density Spin-Transfer Torque Magnetic Random Access Memory (STT-MRAM) with an efficient and high performance write architecture includes core or thin gate devices in global write drivers and local multiplexing gates. The core or thin gate devices are used to deliver a write voltage at a level capable of changing the states of magnetic tunnel junction (MTJ) memory cells, and to multiplex the source line and bit line data. This unique design involves a combination of the write drivers and multiplexing gates to provide a very low impedance path and close to full write voltage level to the MTJ cells, while providing breakdown protection for the thin gate devices to tolerate voltage levels during read and write operations that far exceed the operating voltage range of the core devices. Furthermore, using core devices for drivers in the array area of the STT-MRAM significantly reduces layout area, resulting in increased density.

### CROSS REFERENCE TO RELATED APPLICATIONS

The present application claims the benefit of priority to U.S. Provisional Patent Application No. 63/774,733, filed Mar. 19, 2025, entitled “Efficient and High Performance Write Architecture for High-Density STT-MRAM,” which is incorporated herein by reference in its entirety. The present application is related to U.S. patent application Ser. No. 19/363,553, filed Oct. 20, 2025, and U.S. application Ser. Nos. 19/439,270 and 19/439,272, filed Jan. 2, 2026, each of which is incorporated herein by reference in its entirety.

### TECHNICAL FIELD

The present application is related to resistive-type memory devices, and more particularly to an efficient and high performance write architecture for high-density resistive random access memory.

### BACKGROUND

In the context of semiconductors, a “technology node” (or “design node”) refers to a specific set of manufacturing processes and associated design rules that define the dimensions and capabilities of a chip, typically indicated by the length of the smallest feature that can be manufactured on the chip, such as transistor size. A semiconductor process for a design node (e.g., 28 nm) typically includes different types of metal-on-semiconductor field-effect transistor (MOSFET or MOS) devices, such as input/output (I/O) MOSFET devices and core MOSFET devices, as well as other passive devices such as resistors and capacitors.

I/O MOSFET devices (or I/O devices) have thicker gate oxide (e.g., 60 Angstrom) and thus higher operating voltage range and limit (e.g., 1.6v to 3.6v) depending on the types of I/O devices. These I/O devices in general have longer channel length (e.g., 500 nm or longer) and therefore higher ON resistance or impedance and lower drive current. For example, the Idsat (saturation current) of an I/O NMOS device could be 500 μmA/μm.

Core MOSFET devices (or core devices) have thinner gate oxide (e.g., 15 Angstrom) and lower operating voltage range and limit (e.g., 0.8v to 1.1v). The core devices in general have shorter channel length (e.g., ~30 nm) and therefore lower ON resistance or impedance and higher drive current. For example, the Idₛₐₜ (saturation current) of a core NMOS device could be 800 μA/μm or higher. However, due to their thin gate oxide thickness and shorter channel length, core devices are more susceptible to dielectric breakdown (TDDB) and hard breakdown (VDS or source-drain breakdown) than I/O devices.

The current state of the art magnetic tunnel junction (MTJ) memory requires a write voltage level higher than 1.6v which is outside the operating voltage range of the core devices. A write voltage level between 0.9v to 1.1v (within the operating range of core devices) is insufficient to write to the MTJ.

Conventional write drivers using I/O devices to deliver a write voltage can meet the write voltage level requirement. However, the I/O devices are bigger and have much higher driver impedance and lower drive current than core devices. Thus, using I/O devices in write drivers can significantly reduce the probability of a successful write to the MTJ.

Using I/O devices in write drivers are also undesirable because the write drivers of an MTJ memory device need to be located in the memory array area. The I/O drivers, due to its longer channel length, are difficult to fit in the memory array area while meeting the layout pitch requirements of the MTJ and access transistors cells. This makes the use of I/O devices as write drivers in MTJ memory inferior in performance and size.

### SUMMARY

The present disclosure provides an efficient and high performance write architecture for resistive random-access memory (ReRAM or RRAM), such as high-density spin-transfer torque magneto-resistive random-access memory (STT-MRAM or MRAM).

The architecture comprises global write drivers and local multiplexing gates to deliver near full write voltage level to the MTJ during write operation. In some embodiments, core devices are used to form write drivers, which have the lower driver impedance that significantly improves the probability of a successful write. To meet the operation voltage and reliability requirements, these core devices are not used as single and individual core devices with direct connection to write voltage power supply and ground. Instead, the core devices are connected in series or as stacked devices, are fully protected against breakdown, and can meet the reliability requirements. Even when connected in series, these core devices still provide much lower drive impedance and higher drive current than the use of a single I/O device.

A resistive random-access memory (ReRAM) device according to some implementation examples comprises an array of bit cells, including bit cells arranged in a first number of rows and a second number of columns, the second number of columns being arranged in a plurality of column groups, each column group of the plurality of column groups including a third number of columns. Each bit cell has a control terminal and two current carrying terminals, each bit cell in a row has its control terminal coupled to a word line (WL) of the row, and each bit cell in a column has at least two current carrying terminals coupled, respectively, to a bit line (BL) and a source line (SL) of the column.

The ReRAM device further includes global write drivers operable to drive signals to bit cells in respective columns in a selected column group of the plurality of column groups, and a plurality of local drive units corresponding, respectively, to the plurality of column groups, a respective local drive unit of the plurality of local drive units including local multiplexing gates corresponding to respective columns in a respective column group. Each local multiplexing gate is coupled to the BL and SL of a respective column of the respective column group. The respective local multiplexing gate includes a first set of transistors, and the respective global write driver includes a second set of transistors corresponding, respectively, to the first set of transistors. A first transistor of the first set of transistors and a first corresponding transistor of the second set of transistors are serially connected between one of the SL and BL of the respective column and one of first and second supply voltage terminals of the ReRAM device. A second transistor of the first set of transistors and a second corresponding transistor of the second set of transistors are serially connected between the other one of the SL and BL of the respective column and the other one of first and second supply voltage terminals.

In some implementation examples, the first set of transistors include a first p-type transistor and a first n-type transistor, the second set of transistors include a second p-type transistor and a second n-type transistor, the second p-type transistor, the first p-type transistor, the first n-type transistor, and the second n-type transistor are coupled to each other in series between the first and second supply voltage terminals, and a first node between a current-carrying terminal of the first p-type transistor and a current-carrying terminal of the first n-type transistor is coupled to one of the BL and SL of the respective column.

In some implementation examples, the second p-type transistor, the first p-type transistor, the first n-type transistor, and the second n-type transistor have a plurality of input gates, and the plurality of gates including a first gate configured to receive a first control voltage and a second gate configured to receive a second control voltage, the first control voltage to swing between the first supply voltage and a halfway voltage, the second control voltage to swing between the halfway voltage and the second supply voltage, the halfway voltage being about halfway between the first supply voltage and the second supply voltage.

In some implementation examples, the respective local multiplexing gate and the respective global write driver are configured to drive the first node to a first voltage level close to the first supply voltage when writing a first value to a bit cell in the respective column of bit cells, and to drive the first node to a second voltage level close to the second supply voltage when writing a second bit value to a bit cell in the respective column of bit cells.

In some implementation examples, each transistor in the first and second sets of transistors has a control terminal and two current carrying terminals, and is characterized by a set of parameters including a first limit on voltage across the control terminal and one of the two current carrying terminals and a second limit on voltage across the two current carrying terminals. The first and second supply voltage terminals are configured to receive first and second supply voltages, respectively. A voltage difference between the first supply voltage and the second supply voltage significantly exceeds each of the first and second limits. The voltage difference is significantly greater than a source-drain breakdown voltage of each of the first and second set of transistors.

In some implementation examples, the voltage difference exceeds a programming voltage required to flip a resistance state of the MTJ structure from a low-resistance state to a high-resistance state, or vice versa.

In some implementation examples, each bit cell in the array of bit cells includes at least one select transistor and at least one magnetic tunnel junction (MTJ) structure, and wherein the at least one select transistor has an operating voltage range about the same as the operating voltage range of one of the first and second set of transistors.

In some implementation examples, each of the respective local multiplexing gate and the respective global write driver is further configured to receive a halfway voltage, the halfway voltage being about halfway between the first supply voltage and the second supply voltage.

In some implementation examples, the respective local drive unit further includes a local column select drive configured to generate a column select signal that swings between the first supply voltage and the halfway voltage.

In some implementation examples, the local column select drive includes level shifter circuitry having a first control input, and first and second outputs configured to output, based on a signal at the first control input, first and second voltages, respectively, or second and first voltages, respectively, the first voltage about equal to the first supply voltage, the second voltage about equal to the second supply voltage.

In some implementation examples, the main driver of the global write drivers uses the write voltage (VWR) or as the power supply. VWR is a high voltage write level (e.g., 1.6v to 2.2v) that is required for a successful write to the MTJ, meaning that the driver is configured to provide the necessary threshold voltage across the MTJ and sufficient current to switch the MTJ's resistance state from a low-resistance state (parallel or P-state, with resistance Rp) to a high-resistance state (anti-parallel or AP-state, with resistance Rap), or vice versa, i.e., from Rap to Rp, for all voltage, process, and temperature corners.

In some implementation examples, to resolve the source-drain breakdown reliability issue of using core devices in the write drivers, the main drivers, and the multiplexing gates are connected together to form a series device. With the gates of the core devices in the series device controlled with an appropriate voltage level VG, the full differential write voltage level (VWR−VSS) does not appear across the VDS of each of the serially connected core devices. Instead, there will be a voltage drop close to the value of VWR−VG across each of the series connected core devices. This puts the VDS of each of the series connected core devices within the VDS limit and safe operating range of core devices.

Even when the core devices are connected in series, if the source or drain of any of the core devices is connected to VWR, the gate cannot be toggled between ground and VWR as this will exceed the VGS limit of the core device and will potentially cause dielectric breakdown over time.

To resolve the dielectric breakdown reliability issue, a half VWR internal voltage (VHVWR), for example 0.9v, is introduced to limit the gate of a PMOS driver to toggle between VHVWR (0.9v) and VWR (1.8v). In essence, the input gate voltage magnitude between VHVWR and VWR is VWR−VHVWR, which, for example, is 1.8v−0.9v=0.9v. The VGS limit for safe operation of core devices corresponds to the operating range of the core devices (e.g., 0v−1.1v), which is set by the manufacturer of the devices. Thus, VGS=0.9v is within this operating range and is considered meeting the limit corresponding to the safe operating range of the core devices.

With the reliability issues resolved, the series connected core devices now behaves as a single core device with slightly longer channel length than an IO device used for the same purpose but with much lower drive impedance and higher drive current.

Furthermore, using core devices allows the write drivers and multiplexing gates to be laid out in the pitch of the MTJ memory cells which can significantly reduce overall chip area.

### BRIEF DESCRIPTION OF THE DRAWINGS

FIGS. 1A-1D are schematic diagrams of an MRAM device according to the present disclosure.

FIG. 2 is a circuit diagram of a global write driver according the present disclosure.

FIG. 3 is a circuit diagram of local multiplexing gates according to the present disclosure.

FIG. 4 is a circuit diagram of an MTJ memory cell unit according to the present disclosure.

FIG. 5 is a circuit diagram of a local column select drive unit according to the present disclosure s.

FIG. 6 is a circuit diagram of a write voltage level shifter circuit that is part of the local column select drive circuit, the level shifter to translate a signal of VDD level (0.9v) to a signal of VWR (write voltage) level (1.8v), according to the present disclosure.

FIG. 7 is a diagram of an MTJ memory cell unit, including a cell access transistor N0, showing the VDS of the access cell transistor, the differential voltage across the MTJ, as well as the differential voltage between SL and BL, according to the present disclosure.

FIG. 8 is a waveform diagram showing comparison of the differential voltage (SL-BL) between a write method according to some implementation examples and a conventional write method when writing a ‘1’ to the MTJ cell.

FIG. 9 is a waveform diagram showing the SL level, the SLP, SLN intermediate levels, and the VDS of the stacked write driver devices when the write driver is ON and writing a 1′ to an MTJ cell, indicating that the stacked write drivers are protected against breakdown in a process of writing a 1′ to the MTJ cell according to the present disclosure.

FIG. 10 is a waveform diagram showing comparison of the differential voltage (SL-BL) between a write method according to some implementation examples and a conventional write method when writing a ‘0’ to the MTJ cell.

FIG. 11 is a waveform diagram showing that the stacked write drivers are protected against breakdown in a process of writing a ‘0’ to the MTJ cell according to the present disclosure.

FIGS. 12A and 12B are diagrams of an MTJ bit cell unit, showing the VDS of the access cell transistor, the differential voltage across the MTJ, as well as the differential voltage between SL and BL, in processes of writing ‘1’ and writing ‘0,’ respectively, according to the present disclosure.

FIGS. 13A and 13B are diagrams of an MTJ bit cell unit, showing the VDS of the access cell transistor, the differential voltage across the MTJ, as well as the differential voltage between SL and BL, in conventional processes of writing ‘1’ and writing ‘0,’ respectively.

FIGS. 14A and 14B are diagrams showing that a series or stacked devices are protected when a driver is enabled to write ‘1’ and to write ‘0,’ respectively, as the levels of VGS and VDS of each of the stacked devices are within the operating range and limit of core devices, according to the present disclosure.

### DESCRIPTION OF THE EMBODIMENTS

### Main Power and Signal Description

VDD—Core device power supply (0.9v).
VWR—Write voltage supply for the write drivers. This is the voltage level required to perform a successful write to the memory cell. VWR can vary between 1.5v to 2.2v.
VSS—ground (e.g., 0V).
VHVWR—Halfway VWR power supply. VHVWR tracks VWR to about half or 50% of VWR level. If VWR=1.8v, then VHVWR is approximately 0.9v. In some embodiments, VHVWR is generated on chip using, for example, a conventional voltage divider coupled between VWR and VSS, and configured to output VHVWR about halfway between VWR and VSS. VWR and VHWR are power supplies for circuitry forming the write architecture according to some embodiments. For example, when the source of the series device is connected to VWR, the VHVWR level, applied to the gates of the core devices in the series device, is sufficient to fully turn on the core devices without causing reliability issues because VSG=0.9v does not violate or exceed the operating range or limit of the core devices.

### Signals

WL—Wordline. WL is connected the gate of the access transistor of the memory cell. This signal is usually boosted to a high voltage level, for example, 2.0v.
CS—Column select signal. Enable the decoded column multiplexing gates to allow write and read access to and from memory cells.
DW—Write data. Data to be written to the memory cells.
ENW—Write enable control signal. When enabled, write access to the memory cells is allowed.
ENR—Read enable control signal. When enabled, read access from the memory cells is allowed.
SAE—Sense amplifier enable. Turns on the sense amplifier to sense the analog data from memory cells and outputs to digital data.
SLP—Intermediate node of the P series write driver between VWR and SL.
SLN—Intermediate node of the N series write driver between SL and VSS.
BLP—Intermediate node of the P series write driver between VWR and BL.
BLN—Intermediate node of the N series write driver between BL and VSS.
SL—Source line data. When writing a ‘1’, SL is driven to VWR level. When writing a ‘0’, SL driven to VSS level.
BL—Bit line data. When writing a ‘1’, BL is driven to VSS level. When writing a ‘0’, SL driven to VWR level.
CSP—Column select signal that controls the gate of one of the P series write driver. Switches between VHVWR=0.9v and VWR=1.8v.
CSB—Column select signal that precharges the SL and BL to VSS.

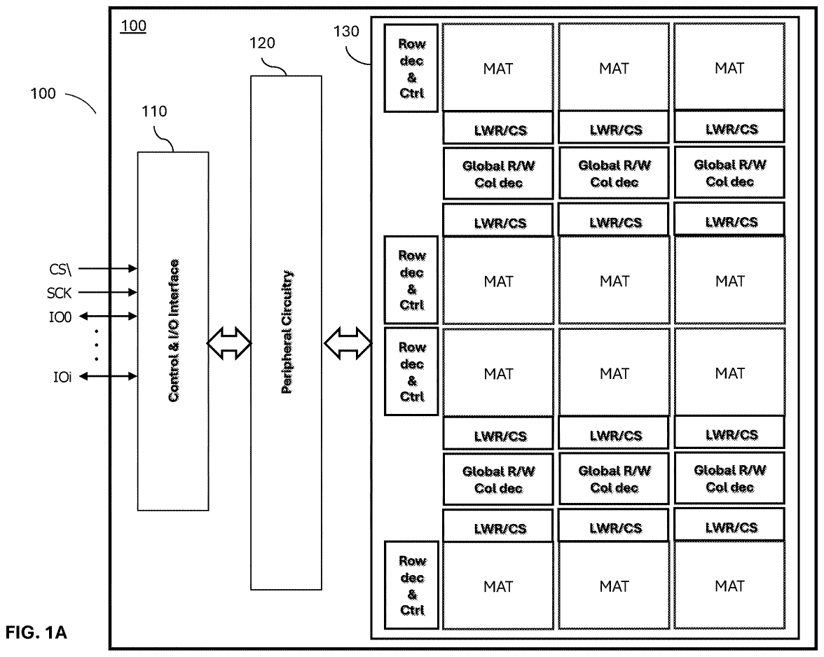

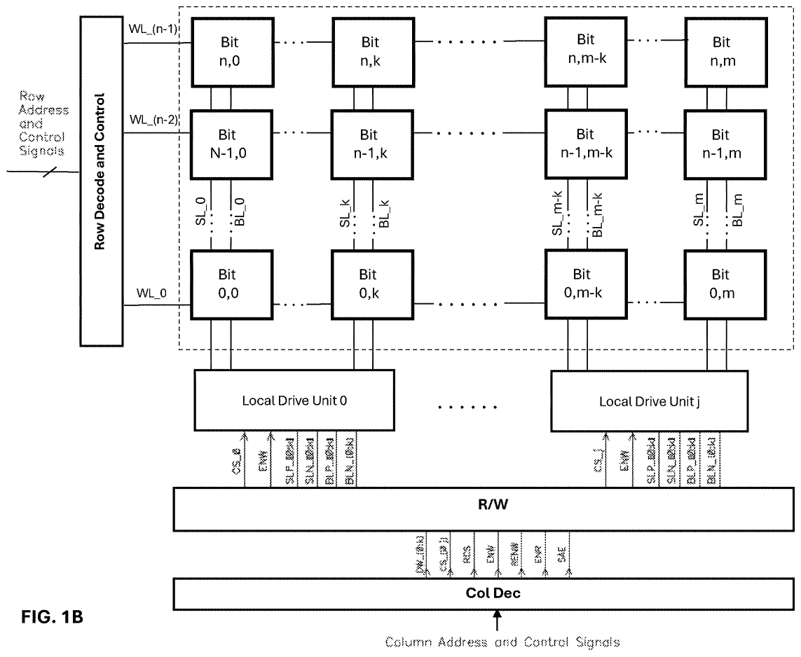

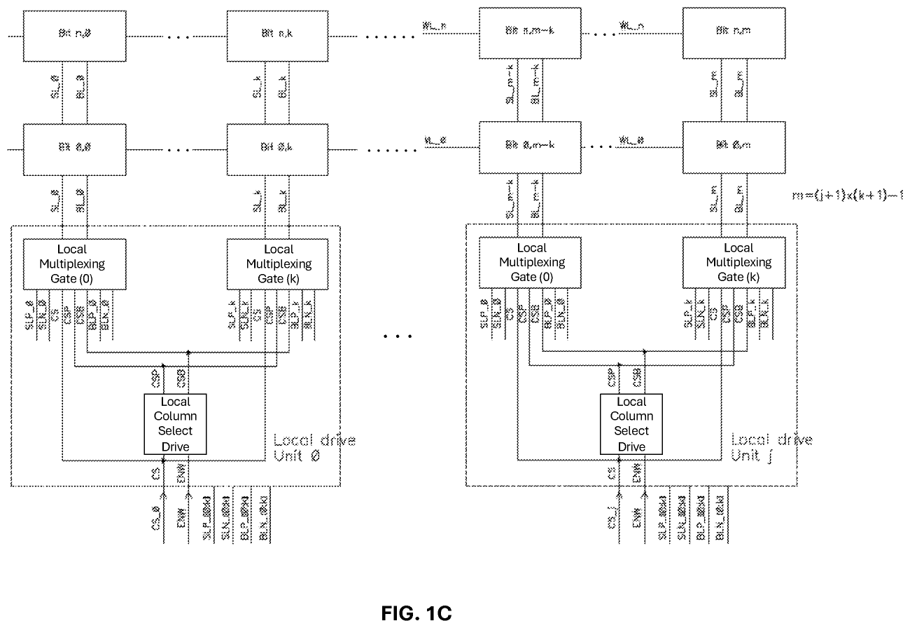

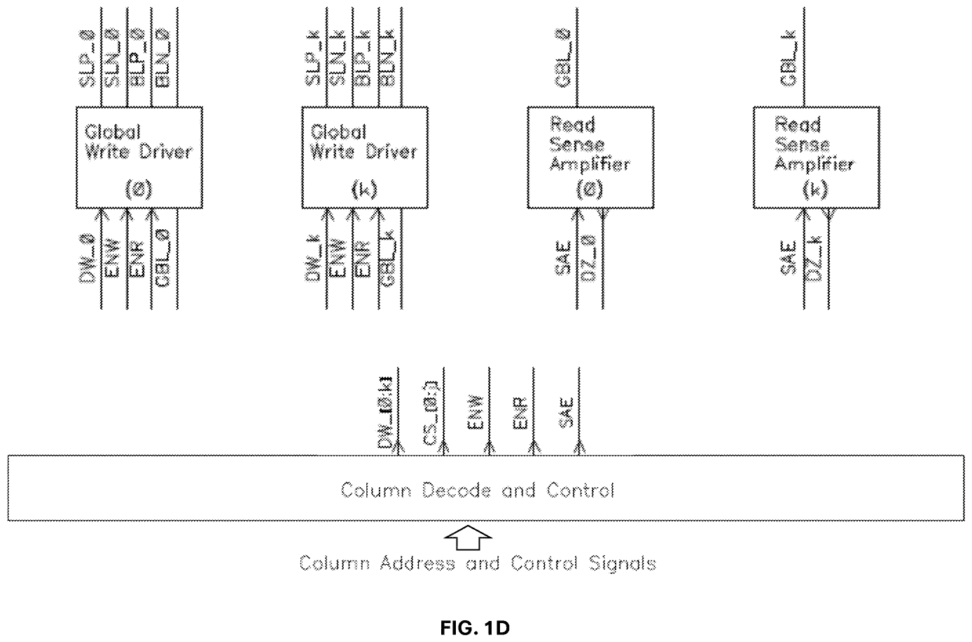

FIG. 1A is schematic diagram illustrating a resistive random access memory (ReRAM) device 100, which can be, for example, a high-density spin-transfer torque magneto-resistive random-access memory (STT-MRAM or MRAM) device, according to some implementation examples. As shown, the ReRAM (e.g., MRAM) device 100 includes control and I/O interface 110, peripheral circuitry 120, and a memory core 130. The memory core 130 includes a plurality of memory array tiles (MAT), a respective local write/read and column select (LWR/CS) circuitry associated with each MAT, a respective row decoder and control circuit (Row dec & Ctrl) for each row of MAT's, and global read/write and column decoder circuits (Global R/W Col dec). In some implementation examples, a plurality of MATs in each column of MATs share a respective global read/write and column decoder circuit.

In some implementation examples, the control and I/O interface 110 can be any of a variety of Serial Peripheral Interface (SPI) interfaces, such as single channel SPI, extended SPI (xSPI) with dual data, quad data, dual IO or quad IO, multi-channel SPI with DPI or QPI, etc. Other types of I/O interfaces such as a parallel bus interface, where command and address (C/A) signals and data signals are communicated via designated signal lines can also serve as the I/O interface 110, as the embodiments described herein, do not require any particular kind of I/O interface.

FIG. 1B shows a schematic diagram of an MAT including an (n+1)×(m+1) MRAM memory array, together with associated circuitry including a row decode and control block, a column decode and control block, global write drivers, read sense amplifiers, local column select drive, and local multiplexing gates, according to some implementation examples. The MAT and its associated circuitry are configuration to carry out a memory operation to read from or write to selected bit cells, the memory operation including one or more row operations and one or more column operations.

In a row operation, the row decode and control block decodes the row address signals and generate WL signals, WL_0 to WL_(n−1) based on the decoded row address signals and row control signals supplied by the peripheral circuitry. Each WL signal (or WL) is connected to the gate of the access transistors in a corresponding row across the m columns. However, only 1 out of n WLs is enabled and is driven to a high voltage level (e.g., 2.0 V). Once a WL is enabled, the memory array is ready for the one or more column operations (i.e., write or read operations).

In a column operation, column address and control signals are applied by the peripheral circuitry to the column decode and control block to generate a set of control signals including CS_[0:j], ENW, ENR, SAE signals. ENW, ENR, SAE are common signals throughout all the array blocks.

Referring to FIGS. 1C-1D, during a write operation, DW_[0:k] are input write data to the global write drivers. The k+1 units of global write drivers are common and shared with j+1 units of the local column select drive and local multiplexing gates block. The k+1 units of global write drivers are enabled at the same time. With ENW asserted and one of CS_[0:k] is enabled, the global write drivers generate output SLP_[0:k], SLN_[0:k], BLP_[0:k], BLN_[0:k], which are intermediate source line and bit line data and go to the local multiplexing gates. At the same time, the local column select drive takes 1 of CS_[0:k] input and outputs CSP and CSB signals. CSP is used to control the multiplexing gates for breakdown protection. CSB is for precharging the SL and BL after the completion of the write operation. The outputs of the local multiplexing gates are the final source line and bit line data and go to the selected memory cells to complete the write operation to the cells.

During a read operation: The source line (SL) data is grounded. The power within the read sense amplifier supplies the current through the bit line (BL) N series devices of the write drivers, the multiplexing gates, and then to the MTJ. Depending on the MTJ resistance state, the current will be certain values corresponding the low resistance state (Rp) or high resistance state (Rap). The sense amplifier senses the difference between this current value and a known or reference current value and outputs to DZ_[0:k] of the read sense amplifier digital values of 0 (VSS level) or 1 (VDD level). The reference current can be value that lies between current values corresponding to Rp and Rap. The reference current can also be a value that is always corresponding to an opposite resistance state. For example, if the current is corresponding to a Rp state, then the reference current will also be from an Rap state and vice versa.

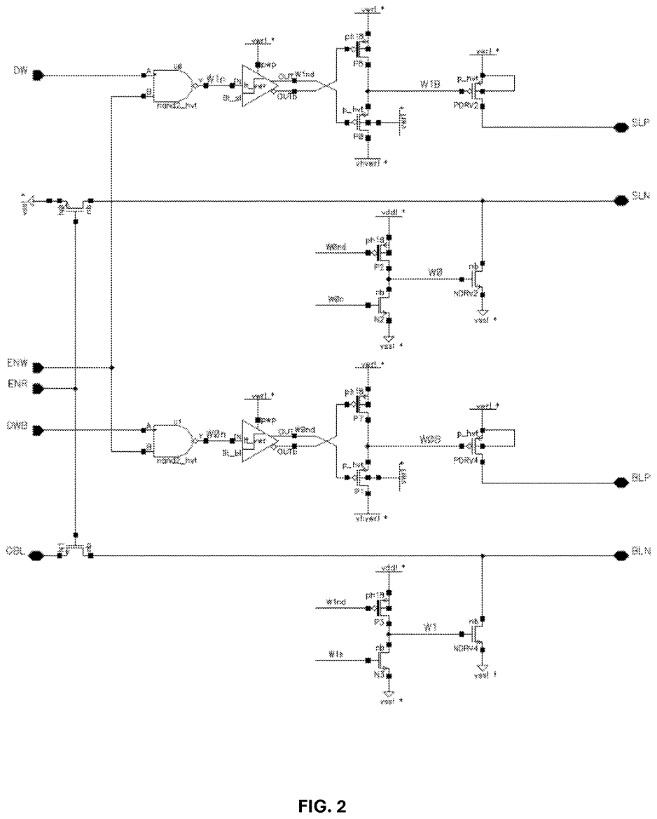

Referring to FIG. 2, which shows circuitry of a global write driver unit according to some implementation examples. The input signals to the global write driver unit are DW, DWB, ENW, and ENR. DWB is the inversion of DW. The output signals are SLP, SLN, BLP, and BLN. GBL is a bidirectional signal line. The write driver also includes a level shifter to translate a signal of VDD level (0.9v) to VWR level (1.8v), as discussed below.

In the following description, unless specified otherwise, a low state is equivalent to a VSS level or logic low or 0. A high state is equivalent to a VDD level or logic high or 1. Initially when the driver is in the off state, ENW is low. Both W1n and W0n are high. W1nd and W0nd go to VWR high level which turns off P0 and P1. The OUTb of both level shifters goes low which enables P5 and P7 and takes both W1B and W0B to VWR level. This turns off PDRV2 and PDRV4. W0n and W1n high also brings W0 and W1 to low which turns off NDRV2 and NDRV4. So initially when the global write driver is off, SLN and BLN are tri-stated.

When writing a ‘1’, DW is high, DWB is low. With ENW asserted high, W1n goes low which causes OUTb of the Ilt_sl level shifter to go to the VWR level. This turns off P5. At the same time, W1nd goes low and enables P0 which drives W1B to VHVWR level (0.9v). So PDRV2 is on with the gate at VHVWR level. Even though W1B is at VHVWR level, the VSG of the PDRV2 is actually 0.9v (VWR−VHVWR) which is the equivalent of a full VSG level of a core device. Therefore, SLP is strongly driven to near VWR level.

At the same time, DWB low forces W0n high and consequently, W0nd goes to VWR high level and this turns off P2 and turns on N2 which drives W0 to 0v and turns off NDRV2. Similarly, W1n low and W0n high forces W0B to VWR high level and W1 to high which turns off PDRV4 and turns on NDRV4. This drives BLN to low.

When writing a ‘0’, DW is low, DWB is high. The internal signals W1n, W1nd, W0n, W0nd are inverse of writing a ‘1’. The result is that W1B is driven to VWR high level which turns off PDRV2 and W0 is driven to high which turns on NDRV2 and drives SLN to low. At the same time, W0B is driven to VHVWR level which turns on PDRV4 and W1 is driven to low which turns off NDRV4. This drives BLP to near VWR high level.

In summary, when writing a ‘1’, DW=high, DWB=low, W1B=VHVWR level, PDRV2 is on, SLP is near VWR level. Further, W0=low, NDRV2 is off, SLN is near an intermediate level, W0B=VWR level, PDRV4 is off, BLP is near the intermediate level, W1=high, NDRV4 is on, BLN is low

When writing a ‘0’, DW=low, DWB=high W1B=VWR level, PDRV2 is off, SLP is near the intermediate level. Further, W0=high, NDRV2 is on, SLN is low, W0B=VHVWR level, PDRV4 is on, BLP is near VWR level, W1=low, NDRV4 is off, BLN is at the intermediate level

VWR can be used as a power supply for I/O devices. For example, VWR can be connected directly to the source or drain of a single I/O device (PMOS or NMOS) with its gate switching between ground and VWR voltage level. This operation does not cause any reliability issues.

In some implementation examples, the global write driver includes core devices and VWR is used as a power supply for the core devices. However, VWR is not applied directly across the source and drain of a single core device (PMOS or NMOS) with its gate switching between ground and VWR voltage level, as this operation exceeds the voltage operating range and limit of the core devices and can cause potential breakdown and reliability issues.

As mentioned previously, there are two breakdown mechanism associated with using the core devices for write driver design. One is dielectric breakdown in which the VGS limit of the core devices is exceeded over a period of time. This is a time-dependent dielectric breakdown (TDDB) failure mechanism in which the gate oxide will eventually breakdown after a period of time. The other is hard breakdown (or source-drain VDS breakdown). This occurs when the source-drain voltage exceeds the BVDS (source-drain breakdown) limit (e.g., 2.5V) of the core devices.

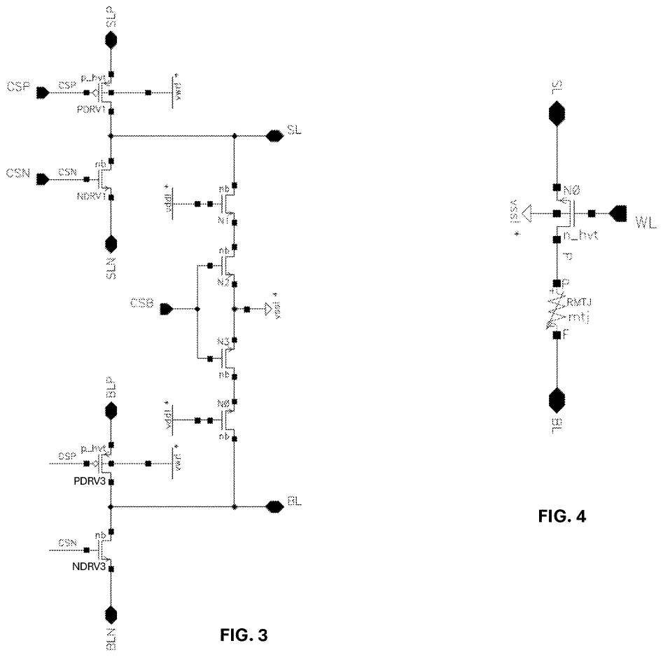

FIG. 3 shows circuitry of a local multiplexing gate unit according to some implementation examples. The multiplexing gate unit functions as pass gates to select the corresponding set of SL and BL when CSP and CSN are enabled (where CSN corresponds to CS). It also serves an additional purpose, which is to protect against breakdown of the core devices in the global write driver, as the core devices in the local multiplexing gate unit form series devices with core devices in the global write drivers (i.e., corresponding core devices in the local multiplexing gate unit and the global write drive are connected in series between VWR and ground). For example, as shown in FIGS. 2 and 3, core device PDRV1 in the local multiplexing gate and core device PDRV2 in the global write driver are connected in series between VWR and SL via the SLP node, core device NDRV1 in the local multiplexing gate and core device NDRV2 in the global write driver are connected in series between SL and VSS via the SLN node, core device PDRV3 in the local multiplexing gate and core device PDRV4 in the global write driver are connected in series between VWR and BL via the BLP node, and core device NDRV3 in the local multiplexing gate and core device NDRV4 in the global write driver are connected in series between BL and VSS via the BLN node. In some implementation examples, the local multiplexing gate unit also includes stacked core devices N0, N1, N2, N3 to precharge SL and BL to VSS when in standby state. The multiplexing gate unit has control inputs CSP, CSN, CSB, and bidirectional terminals SLP, SLN, BLP, BLN, SL, BL.

### During Write

CSP is low, CSN is High, PDRV1, NDRV1, PDRV2, NDRV2 are on.
CSB is low, N2, N3 off, precharge is off.
SL and BL data is valid and depends on whether it is writing ‘1’ or ‘0’.

To write ‘1’: SLP is near VWR level, SL is near VWR level. This forces SLN to an intermediate level. BLN is at VSS, BL is at VSS. This forces BLP to an intermediate level.

To write ‘0’: SLN is VSS, SL is VSS. This forces SLP to an intermediate level. BLP is near VWR level, BL is near VWR level. This forces BLN to an intermediate level.

### During Read

CSP is VWR high, CSN is VDD high, source line path is grounded (SL->SLN->VSS).
Current flows path: Sense amplifier->NDRV2->MTJ->access transistor (N0 of FIG. 4)->SL->SLN->VSS. The MTJ resistance state determines the strength of the current value. The sense amplifier takes this current value and compare with a known or reference current and outputs a digital high (VDD) or low (0v) value.

### During the Idle State (When Write or Read is not Active)

CSP is high, CSN is low, PDRV1, NDRV1, PDRV2, NDRV2 are off.
CSB is high, precharging both SL and BL to VSS (0v).

Thus, as shown in FIGS. 2 and 3, in some embodiments:
PDRV1 (FIG. 3) and PDRV2 (FIG. 2) form a set of P series core devices PDRV1/PDRV2;
NDRV1 (FIG. 3) and NDRV2 (FIG. 2) form a set of N series core devices NDRV1/NDRV2;
The series device configuration provides a voltage drop to an intermediate level at nodes SLP and SLN, thus protecting the series core devices against a source-drain VDS hard breakdown;
The source of one of the series core devices is connected to VWR while VHVWR (Half VWR), which tracks VWR to about 50% of VWR level, is used to control the gate of these series core devices to stay within the operating range and limit of the core devices;
Nodes W0B, W1B, CSP are designed to switch between VHVWR (0.9v) and VWR (1.8v). At the VWR high level, CSP and W1B are to completely turn off PDRV1 and PDRV2, respectively. The VHVWR (0.9v) low level is sufficient to fully turn on PDRV1 and PDRV2 and yet at the same time helps to protect against dielectric breakdown of the core devices; and
Precharging SL/BL are also implemented with core devices. The gates of N0 and N1 gate are connected to VDD and is used as protection devices against VDS hard breakdown of the core devices N1 and N2, which are used to discharge SL, and the VDS hard breakdown of the core devices N0 and N3, which are used to discharge BL.

Thus, instead of I/O devices, series core devices (e.g., PDRV1/PDRV2, NDRV1/NDRV2, PDRV3/PDRV0, NDRV3/NDRV0, N1/N2, and N0/N3) are used in the global write driver and local multiplexing gate. With protection in place, the series devices behave as a single core device with slightly longer channel length. Even when stacked, the overall channel length of the stacked core devices is still smaller than the channel length of an IO device used for the same purpose. The core devices have much lower drive impedance and much higher drive current, as compared to I/O devices.

FIG. 4 is an MRAM bit cell comprising of access transistor N0 and an MTJ (RMTJ). Source line (SL) is connected to the source of the access transistor and bit line (BL) is connected to the Free layer of the MTJ.

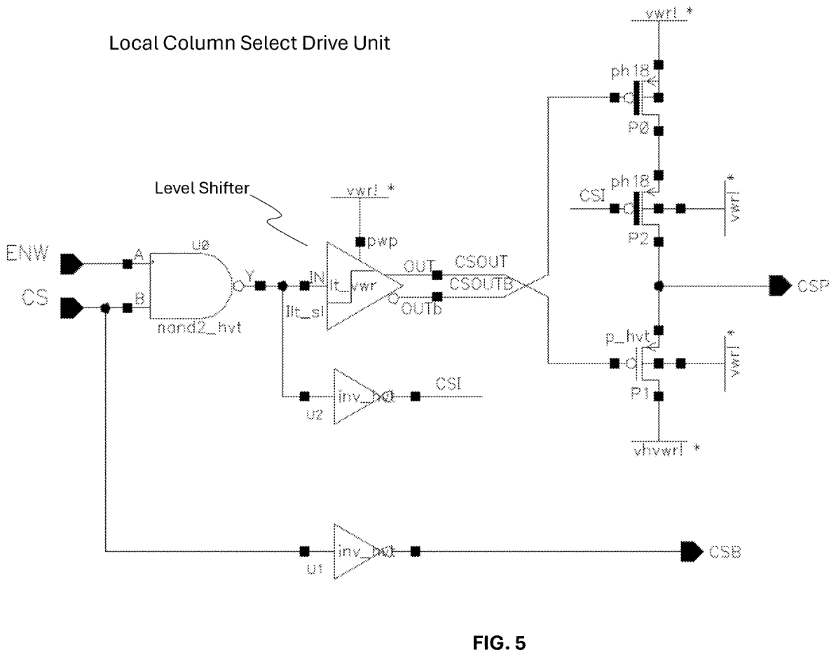

FIG. 5 shows circuitry of the local column select drive unit, which is to generate a column select signal, CSP, that switch between VHVWR (0.9v) and VWR (1.8v) level, similar to W0B and W1B of the global write drivers, according to some implementation examples. CSP needs to go to VWR high level to completely turn off PDRV1 and PDRV2 of the local multiplexing gates of FIG. 3. CSP that goes only to VDD high is not sufficient to turn off PDRV1 and PDRV2 of FIG. 3 because SL and SLP are at VWR high (1.8v) level. When CSP switches from VWR high to a low state, it stops at the VHVWR (0.9v) level. This is equivalent to applying a VSG=0.9v for PDRV1 and PDRV2, which is within the operating range and limit of core devices. CSP does not need to go to VSS, as CSP at VHVWR for the low level is sufficient. Therefore, this arrangement helps to protect the stacked core devices P0/P2/P1 against dielectric breakdown.

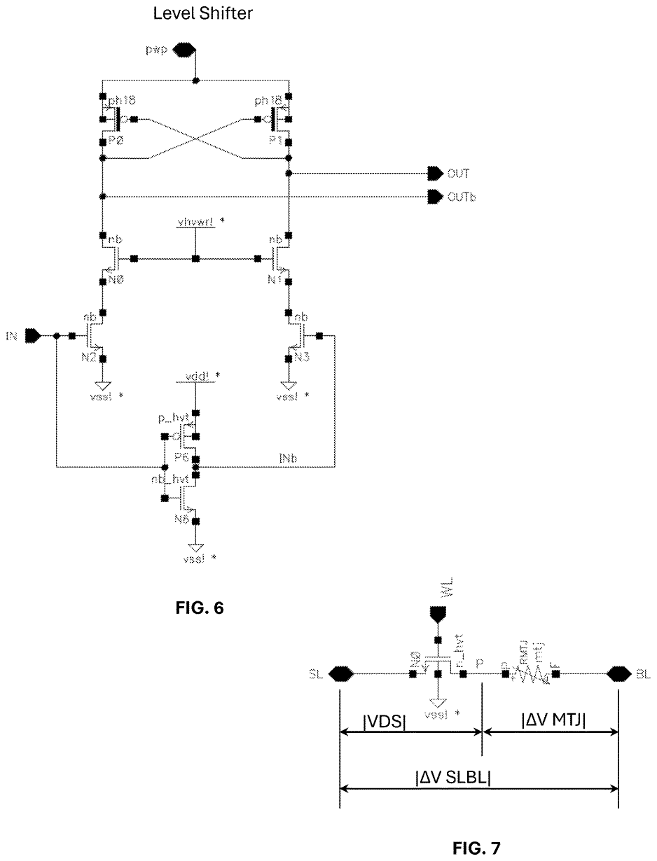

FIG. 6 is the level shifter circuity within the local column select drive, which has the following functions:
When IN is high, OUT is VWR, OUTb is VSS
When IN is low, OUT is VSS, OUTb is VWR

FIG. 7 is a diagram of an MTJ memory cell unit, including a cell access transistor N0, showing:
   |ΔV SLBL|: Magnitude or absolute value of voltage between SL and BL.
   |VDS|: Magnitude or absolute value of VDS of access transistor.
   |ΔV MTJ|: Magnitude or absolute value of voltage across the MTJ.

As described above, when writing from 0 to 1 (writing a ‘1’) on an MTJ, the MTJ resistance changes from Rp (parallel state) to Rap (anti-parallel state). When writing from 1 to 0 (writing a ‘0’), the MTJ resistance changes from Rap (anti-parallel state) to Rp (parallel state). Thus, a successful write to the MTJ means that the driver is configured to provide the necessary threshold voltage across the MTJ and current to change the MTJ's resistance state from Rp to Rap or vice versa from Rap to Rp for all voltage, process, and temperature corners.

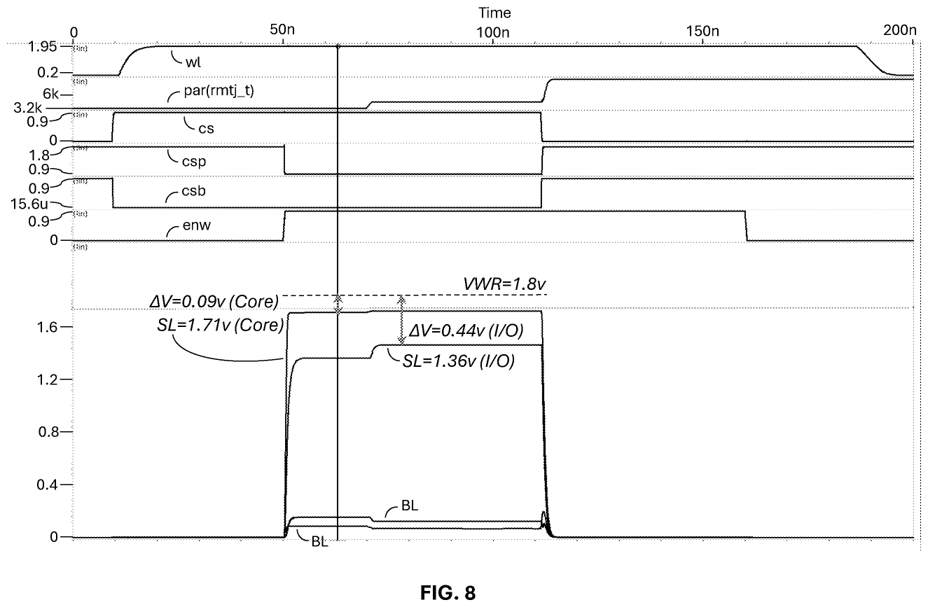

FIG. 8 is a waveform diagram of a set of parameters in the case of writing a ‘1’ (i.e., DW is high, DWB is low) to an MTJ, according to some implementation examples. As shown in FIG. 8, after CS is asserted (i.e., CS goes high, CSB goes low), CSP switches to VHVWR, ENW turns high, and |ΔV| between SL and BL reaches 1.63v and is maintained at the levels for some time, resulting in the change of the resistive state par(rmtj_t) of the MTJ, indicating successful write to the MTJ. For comparison, in a conventional process of writing a “1” to an MTJ, |ΔV| between SL and BL is 1.21v. Since the higher the |ΔV| between SL and BL, the higher the probability of a successful write, the write circuitry using core devices according to some implementation examples is advantageous over conventional circuitry using IO devices.

Furthermore, the smaller voltage drop of 0.09v across the series core devices from VWR=1.8v to SL=1.71v (as compared to the voltage drop of 0.44v from VWR=1.8v to SL=1.36v for IO devices) shows that the drive impedance for the series core devices is much lower, resulting in much higher drive current.

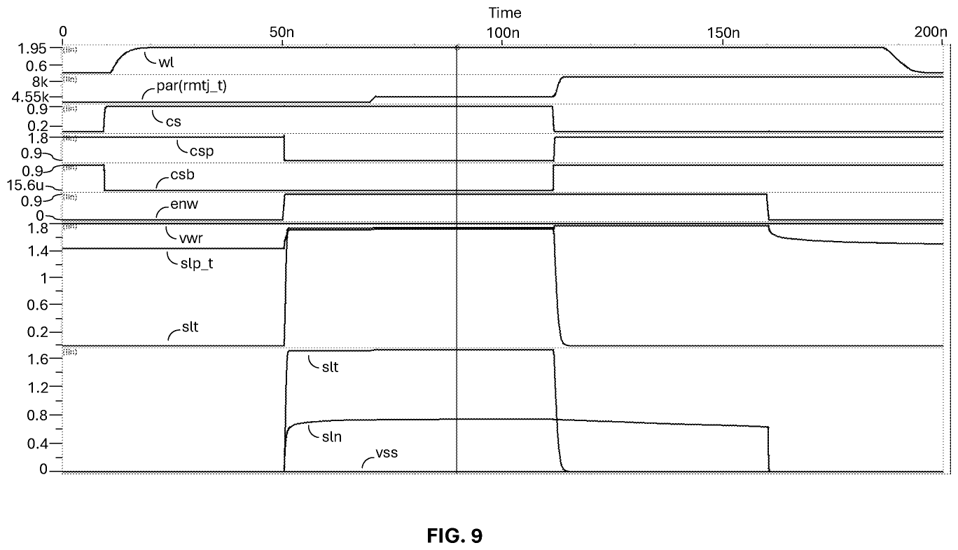

FIG. 9 is a waveform diagram showing the intermediate level nodes of the series or stacked devices and how they are being protected in the process or writing a ‘1.’ As shown, when the write driver is on and is writing a ‘1’:
W1B is VHVWR, CSP is VHVWR, CSN is VDD, W0 is VSS;
SL is near VWR level, SLP is also near VWR level;
The |VDS| of the P series devices is small and does not pose reliability issues; and
SL is near VWR level forces SLN to an intermediate level, thus providing |VDS| for N series devices that is within the operating range and limit of core devices.

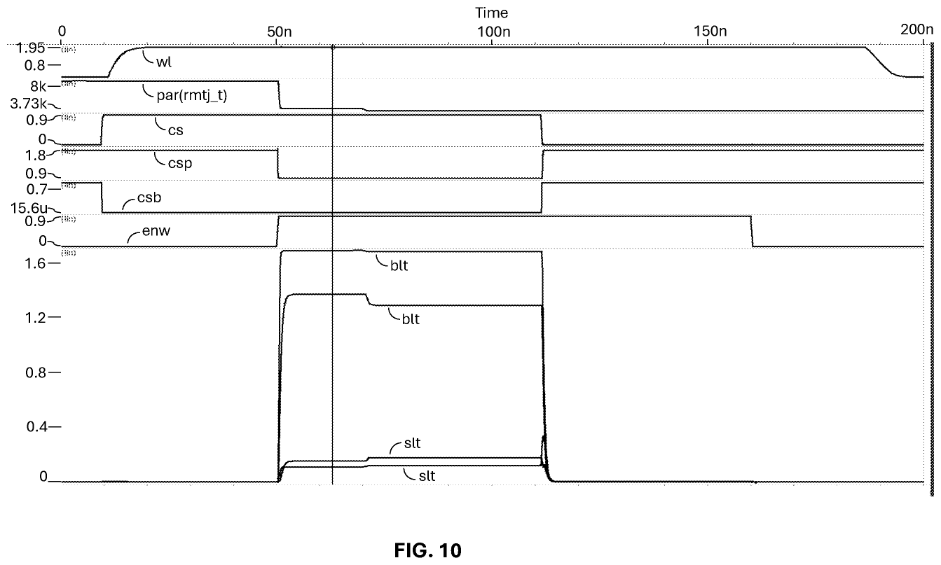

FIG. 10 is a waveform diagram showing the case of writing a ‘0’ to the memory cell, according to some implementation examples. As shown in FIG. 10, when CS is high, CSB is low, CSP is VHVWR, ENS is high, DW is low, DWB is high. Thus, |ΔV| between SL and BL=1.58v is achieved. As comparison, in a conventional process of writing a “0” to an MTJ, |ΔV SLBL|=1.22v.

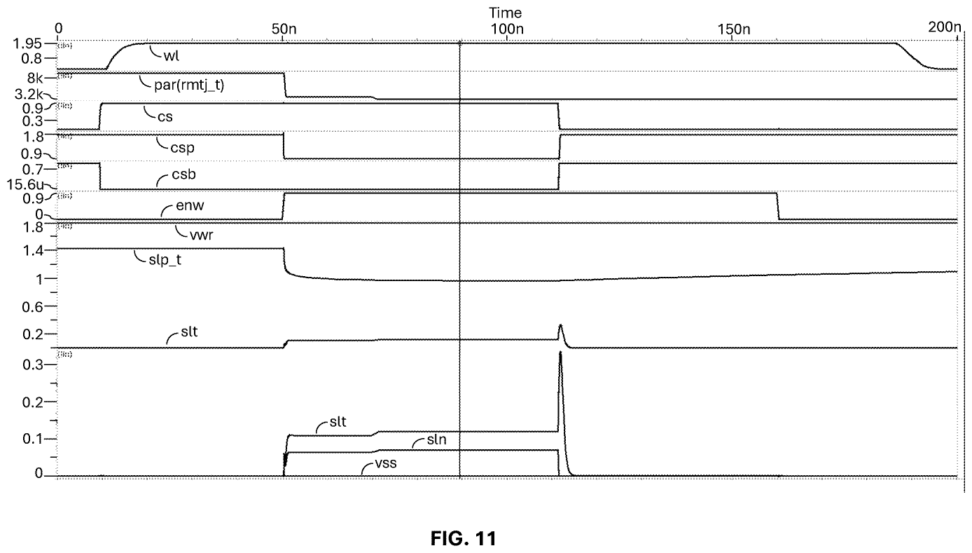

FIG. 11 is a waveform diagram showing the SL level, the SLP, SLN intermediate level nodes, and the VDS of the series or stacked devices to illustrate that they are being protected for the case of writing a ‘0’:

When the write driver is on and is writing a ‘1’: W1B is at VWR, CSP is at VHVWR, CSN is at VDD, W0 is at VDD. SL is at VSS, SLN is also at VSS. The |VDS| of the N series devices is small and does not post reliability issues. SL at VSS forces SLP to an intermediate level, thus providing |VDS| for P series devices that is within the operating range and limit of core devices.

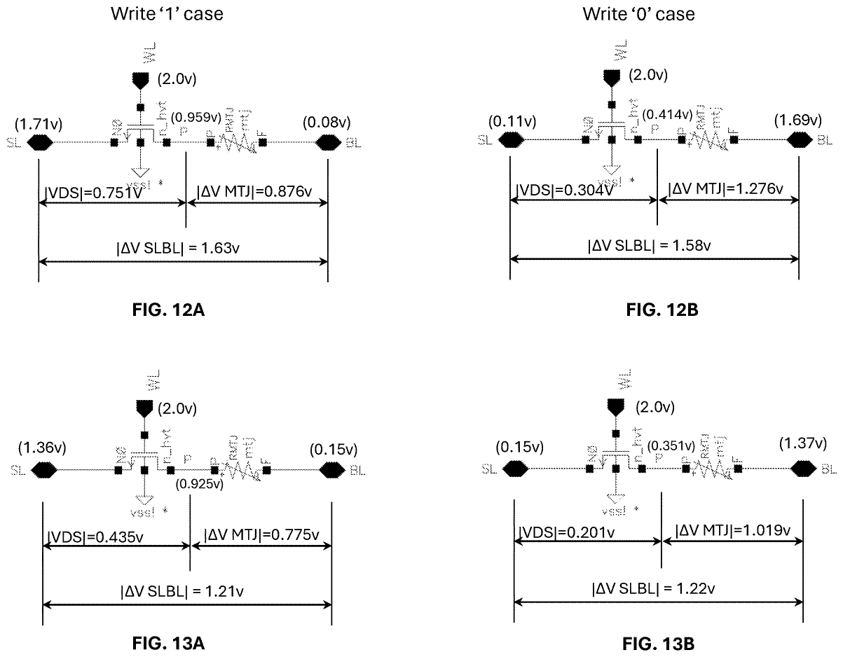

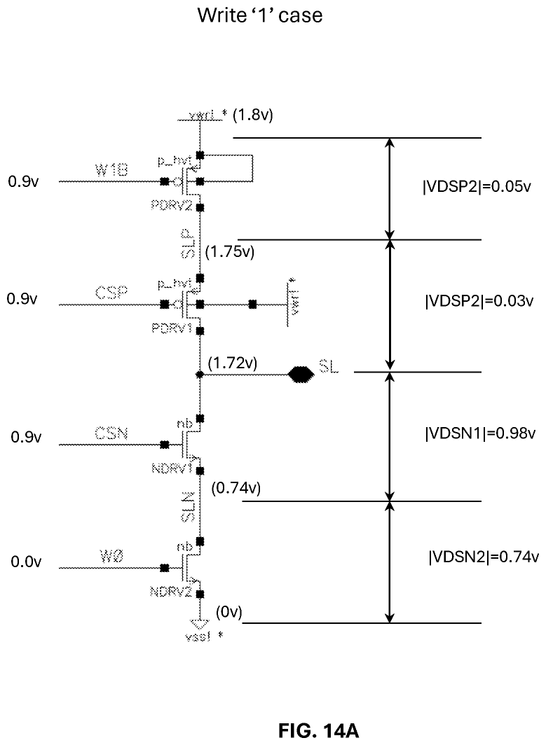

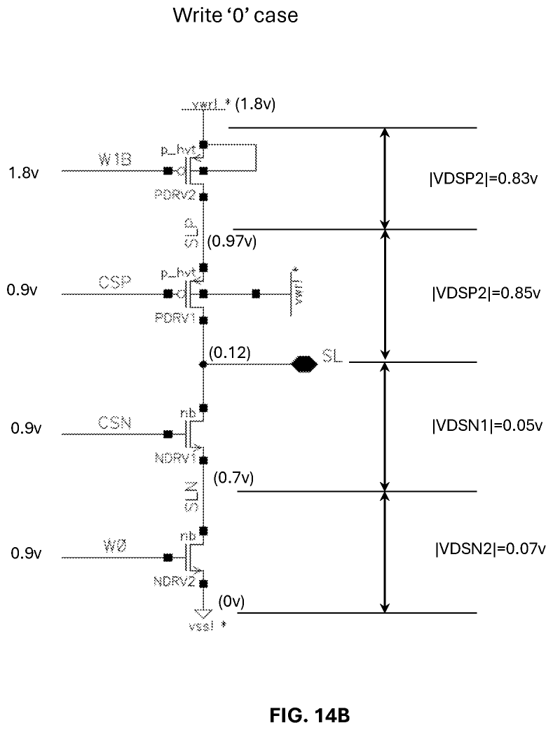

FIGS. 12A and 12B are diagrams of an MTJ bit cell unit, showing key comparison parameters from FIGS. 8 and 10 waveform diagrams in the circuit, e.g., the VDS of the access cell transistor, the differential voltage across the MTJ, as well as the differential voltage between SL and BL, in processes of writing ‘1’ and writing ‘0,’ respectively, according to some implementation examples. As comparison, FIGS. 13A and 13B are diagrams of an MTJ bit cell unit, the VDS of the access cell transistor, the differential voltage across the MTJ, as well as the differential voltage between SL and BL, in conventional processes of writing ‘1’ and writing ‘0,’ respectively. The result shows the advantage of using stacked core devices to achieve higher |Δv| Between SL and BL.
FIGS. 14A and 14B are diagrams showing the key parameters and intermediate node voltage from FIGS. 9 and 11 waveform diagrams in series or stacked core devices. As shown, the series core devices are protected when a driver is enabled to write ‘1’ (FIG. 14A) and to write ‘0’ (FIG. 14B), as the levels of VGS and VDS of each of the stacked devices are within the operating range and limit of the core devices. Thus, the series core devices are protected against dielectric breakdown and source-drain VDS hard breakdown.

It will be understood that various aspects or details of the disclosure may be changed without departing from the scope of the disclosure. It is not exhaustive and does not limit the claimed disclosures to the precise form disclosed. Furthermore, the foregoing description is for the purpose of illustration only, and not for the purpose of limitation. Modifications and variations are possible in light of the above description or may be acquired from practicing the disclosure. The claims and their equivalents define the scope of the disclosure. Moreover, although the techniques have been described in language specific to structural features and/or methodological acts, it is to be understood that the appended claims are not necessarily limited to the features or acts described. Rather, the features and acts are described as example implementations of such techniques.

Furthermore, the description of the different examples of implementations has been presented for purposes of illustration and description, and is not intended to be exhaustive or limited to the examples in the form disclosed. Many modifications and variations will be apparent to those of ordinary skill in the art. Further, different examples of implementations may provide different features as compared to other desirable examples. The example, or examples, selected are chosen and described in order to best explain the principles of the examples, the practical application, and to enable others of ordinary skill in the art to understand the disclosure for various examples with various modifications as are suited to the particular use contemplated.

It will also be understood that, although the terms first, second, etc., are, in some instances, used herein to describe various elements, these elements should not be limited by these terms. These terms are only used to distinguish one element from another. For example, a first circuit could be termed a second circuit, and, similarly, a second circuit could be termed a first circuit, without departing from the scope of the various described implementation examples. The first widget and the second widget are both widget, but they are not the same condition unless explicitly stated as such.

The terminology used in the description of the various described implementation examples herein is for the purpose of describing particular implementation examples only and is not intended to be limiting. As used in the description of the various described implementation examples and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

What is claimed is:

1. A resistive random-access memory (ReRAM) device, comprising:
a first array of bit cells, including bit cells arranged in a first number of rows and a second number of columns, the second number of columns being arranged in a first plurality of column groups, each column group of the first plurality of column groups including a third number of columns, wherein each bit cell has a control terminal and two current carrying terminals, each bit cell in a row has its control terminal coupled to a word line (WL) of the row, and each bit cell in a column has at least two current carrying terminals coupled, respectively, to a bit line (BL) and a source line (SL) of the column;
global write drivers operable to drive signals to bit cells in respective columns in a selected column group of the first plurality of column groups; and
a first plurality of local drive units corresponding, respectively, to the first plurality of column groups, a respective local drive unit of the plurality of local drive units including local multiplexing gates corresponding to respective columns in a respective column group, wherein each local multiplexing gate is coupled to the BL and SL of a respective column of the respective column group;
wherein:
the respective local multiplexing gate includes a first set of transistors, and the respective global write driver includes a second set of transistors corresponding, respectively, to the first set of transistors;
a first transistor of the first set of transistors and a first corresponding transistor of the second set of transistors are serially connected between one of the SL and BL of the respective column and one of first and second supply voltage terminals of the ReRAM device; and
a second transistor of the first set of transistors and a second corresponding transistor of the second set of transistors are serially connected between the other one of the SL and BL of the respective column and the other one of first and second supply voltage terminals.

2. The ReRAM device of claim 1, wherein:
the first set of transistors include a first p-type transistor and a first n-type transistor;
the second set of transistors include a second p-type transistor and a second n-type transistor;
the second p-type transistor, the first p-type transistor, the first n-type transistor, and the second n-type transistor are coupled to each other in series between the first and second supply voltage terminals;
a first node between a current-carrying terminal of the first p-type transistor and a current-carrying terminal of the first n-type transistor is coupled to one of the BL and SL of the respective column.

3. The ReRAM device of claim 2, wherein:
the second p-type transistor, the first p-type transistor, the first n-type transistor, and the second n-type transistor have a plurality of input gates; and
the plurality of gates including a first gate configured to receive a first control voltage and a second gate configured to receive a second control voltage, the first control voltage to swing between the first supply voltage and a halfway voltage, the second control voltage to swing between the halfway voltage and the second supply voltage, the halfway voltage being about halfway between the first supply voltage and the second supply voltage.

4. The ReRAM device of claim 2, wherein the respective local multiplexing gate and the respective global write driver are configured to drive the first node to a first voltage level close to the first supply voltage when writing a first value to a bit cell in the respective column of bit cells, and to drive the first node to a second voltage level close to the second supply voltage when writing a second bit value to a bit cell in the respective column of bit cells.

5. The ReRAM device of claim 1, wherein:
each transistor in the first and second sets of transistors has a control terminal and two current carrying terminals, and is characterized by a set of parameters including a first limit on voltage across the control terminal and one of the two current carrying terminals and a second limit on voltage across the two current carrying terminals;
the first and second supply voltage terminals are configured to receive first and second supply voltages, respectively;
a voltage difference between the first supply voltage and the second supply voltage significantly exceeds each of the first and second limits; and
the voltage difference is significantly greater than a source-drain breakdown voltage of each of the first and second set of transistors.

6. The ReRAM device of claim 5, wherein the voltage difference exceeds a programming voltage required to flip a resistance state of the MTJ structure from a low-resistance state to a high-resistance state, or vice versa.

7. The ReRAM device of claim 1, wherein each bit cell in the first array of bit cells includes at least one select transistor and at least one magnetic tunnel junction (MTJ) structure, and wherein the at least one select transistor has an operating voltage range about the same as the operating voltage range of one of the first and second set of transistors.

8. The ReRAM device of claim 1, wherein each of the respective local multiplexing gate and the respective global write driver is further configured to receive a halfway voltage, the halfway voltage being about halfway between the first supply voltage and the second supply voltage.

9. The ReRAM device of claim 8, wherein the respective local drive unit further includes a local column select drive configured to generate a column select signal that swings between the first supply voltage and the halfway voltage.

10. The ReRAM device of claim 9, wherein the local column select drive includes level shifter circuitry having a first control input, and first and second outputs configured to output, based on a signal at the first control input, first and second voltages, respectively, or second and first voltages, respectively, the first voltage about equal to the first supply voltage, the second voltage about equal to the second supply voltage.

11. The ReRAM device of claim 1, comprising:
a second array of bit cells arranged in a second plurality of column groups, each column group of the second plurality of column groups including a fourth number of columns, each bit cell in a column of the second array of bit cells has at least two current carrying terminals coupled, respectively, to a corresponding pair of BL and SL;
a second plurality of local drive units corresponding, respectively, to the second plurality of column groups, a respective local drive unit of the second plurality of local drive units including second local multiplexing gates corresponding to respective columns in a respective column group of the second plurality of column groups;
wherein:
the global write drivers is further operable to drive signals to bit cells in respective columns in a selected column group of the second plurality of column groups;
the respective second local multiplexing gate includes a third set of transistors corresponding, respectively, to the second set of transistors;
a third transistor of the third set of transistors and the first corresponding transistor are serially connected between one of the SL and BL of a column in the second array of bit cells and one of first and second supply voltage terminals of the ReRAM device; and
a fourth transistor of the third set of transistors and the second corresponding transistor are serially connected between the other one of the SL and BL of the column in the second array of bit cells and the other one of first and second supply voltage terminals.
